(19) United States
(12) Patent Application Publication
(10) Pub. No.: US 2026/0103794 A1
(43) Pub. Date: Apr. 16, 2026

(54) AREA SELECTIVE ATOMIC LAYER THIN FILM DEPOSITION METHOD

(71) Applicant: INHA UNIVERSITY RESEARCH AND BUSINESS FOUNDATION, Incheon (KR)

(72) Inventors: In Hwan BAEK, Incheon (KR); Da Hui JEON, Jeonju-si (KR); In Hong HWANG, Incheon (KR); Min Ki CHOE, Goyang-si (KR); Yoo Hyeon JUNG, Ansan-si (KR); Jae Yoon SHIM, Seoul (KR); Jae Min JUNG, Daejeon (KR)

(21) Appl. No.: 19/358,296

(22) Filed: Oct. 14, 2025

(30) Foreign Application Priority Data
Oct. 14, 2024 (KR) 10-2024-0139413

(51) Int. Cl. C23C 16/04; C23C 16/06; C23C 16/455; C23C 16/56; H01L 21/3205

(52) U.S. Cl. CPC C23C 16/047; C23C 16/06; C23C 16/45553; C23C 16/56; H10P 14/412

(57) ABSTRACT

An embodiment relates to an area selective atomic layer thin film deposition method, including: performing surface treatment using fluorocarbon (CFx) plasma on a non-deposition area of the surface of a substrate; providing a thin film precursor and a reactant to the substrate to selectively form an atomic layer thin film on a deposition area of the substrate surface; and removing any residue remaining on the non-deposition area.

### CROSS REFERENCE TO RELATED APPLICATION

The present application claims priority to Korean Patent Application 10-2024-0139413, filed Oct. 14, 2024, the entire contents of which are incorporated here for all purposes by this reference.

### BACKGROUND

The disclosure relates to an area selective atomic layer thin film deposition method.

With advances in semiconductor industry technology, there are rapid driving of the integration, sophistication, and multi-layering of semiconductor devices. Consequently, the size of semiconductor devices is required to be reduced to 10 nm or less.

As semiconductor device downscaling continues, the complexity of semiconductor manufacturing processes increases, challenging the limitations of conventional top-down patterning methods. For example, edge placement error (EPE) problems arise due to issues such as insufficient device patterning accuracy and misalignment of patterned features during device layering.

EPE occurs during lithography processes due to the inability to accurately align masks with the shrinking device size. This EPE degrades device reliability and durability.

An area selective atomic layer deposition (AS-ALD) method has been proposed as a solution to address EPE problems. AS-ALD is a method for selectively depositing thin films only on the desired surface areas of a semiconductor device structure, eliminating the need for a separate patterning process using a mask.

AS-ALD utilizes surface functionalization using inhibitors to ensure thin films are deposited only on the desired areas. Previous technologies used self-assembled monolayers (SAMs) or small-molecule inhibitors (SMIs) as inhibitors.

SAMs are composed of a head group that selectively forms chemical bonds with the substrate surface and a functional group. The functional group possesses low surface energy and inhibits chemical and physical adsorption of chemical species, and also prevents precursor adsorption during the ALD process, enabling AS-ALD.

However, SAMs are formed through a wet process, making them difficult to apply to mass production due to the long process time of tens of hours or more, their low thermal decomposition temperature limits their application to high-temperature processes; and their long molecular structure (>3 nm) hinders their application to three-dimensional structures due to steric hindrance.

Unlike SAMs, SMIs have smaller molecules, allowing them to be uniformly adsorbed on surfaces and can be used on three-dimensional substrates; however, their relatively poor thermal and chemical stability makes it difficult to achieve substrate selectivity beyond a few nm. Furthermore, the organic compounds constituting these inhibitors are highly likely to cause contamination of semiconductor devices.

Therefore, a technology for forming ultra-fine patterns for unit processes that can overcome these limitations and be mass-produced in actual semiconductor manufacturing is needed; to this end, the development of novel inhibitors and surface treatment methods is required.

### RELATED ART DOCUMENT

### Patent Document

(Patent Document 0001) Republic of Korea Publication Patent No. 10-2024-0097611

### SUMMARY

An aspect of the disclosure is to provide a new inhibitor and surface treatment method for ultra-fine pattern formation technology that reduces process time and enables application in high-temperature processes.

The aspect of the disclosure is not limited to that mentioned above, and other aspects not mentioned will be clearly understood by those skilled in the art from the description below.

An embodiment of the disclosure provides an area selective atomic layer thin film deposition method, including: performing surface treatment using fluorocarbon (CFx) plasma on a non-deposition area of the surface of a substrate; providing a thin film precursor and a reactant to the substrate to selectively form an atomic layer thin film on a deposition area of the substrate surface; and removing any residue remaining on the non-deposition area.

In an embodiment of the disclosure, through the performing of the surface treatment, a fluorocarbon functional group may be formed on the surface of the substrate, and the fluorocarbon functional group may act as an inhibitor that prevents the adsorption of the thin film precursor.

In an embodiment of the disclosure, the performing of the surface treatment using the fluorocarbon plasma may be performed using atmospheric pressure plasma or vacuum plasma equipment.

In an embodiment of the disclosure, the forming of the atomic layer thin film may be performed through an atomic layer deposition process.

In an embodiment of the disclosure, the forming of the atomic layer thin film may be performed at 150° C. to 450° C.

In an embodiment of the disclosure, the thin film precursor may include a ruthenium, platinum or molybdenum metal precursor.

In an embodiment of the disclosure, the reactant may be selected from O₂, O₃, H₂O, H₂O₂, N₂O or metal alkoxide as an oxidizing agent.

In an embodiment of the disclosure, in the forming of the atomic layer thin film, the thin film precursor is adsorbed to the deposition area, and the thin film precursor and the reactant react to form a thin film.

In an embodiment of the disclosure, the thin film precursor may not be chemically adsorbed on the surface-treated non-deposition area of the substrate.

In an embodiment of the disclosure, the removing of the residue may be performed through vacuum or atmospheric pressure O₂ plasma or ozone.

According to an embodiment of the disclosure, since a separate vacuum environment creation and connection blocking or another process is not required through CFx plasma surface treatment, an atomic layer thin film can be deposited area selectively through a simple and short process, and selective deposition of various materials can be possible regardless of the precursor.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating the area selective atomic layer thin film deposition method of the disclosure;

FIG. 2 is an image showing the reaction occurring on the substrate surface during the area selective atomic layer thin film deposition method of the disclosure;

FIG. 3 shows contact angle images (a) before and (b) after CFx plasma surface treatment;

FIG. 4 is an FT-IR graph before and after CFx plasma surface treatment;

FIG. 5 shows XPS data (a) after CFx plasma surface treatment and (b) after CFx residue removal using atmospheric pressure O₂ plasma;

FIG. 6 shows XPS data of a ruthenium thin film (a) before and (b) after atmospheric pressure O₂ plasma treatment;

FIG. 7 shows the results of selective deposition of a ruthenium metal thin film using the area selective atomic layer thin film deposition method of the disclosure;

FIG. 8 shows (a) the interface of a substrate without CFx plasma treatment and (b) a magnified image thereof;

FIG. 9 shows (a) the interface of a substrate after CFx plasma treatment at 250 W for 1 minute, removing all inhibitors, and (b) a magnified image thereof;

FIG. 10 shows images of wafer-scale surface treatment using controlled plasma head movement;

FIG. 11 shows images comparing ruthenium deposition on untreated and treated areas with CFx plasma;

FIG. 12 shows the results of calculating the adsorption energy of a ruthenium precursor on a CFx-treated surface and an untreated SiO2 surface according to the disclosure;

FIG. 13 shows (a) an SEM image and (b) EDS analysis results of a substrate on which a ruthenium thin film was selectively deposited according to the disclosure; and

FIG. 14 is a graph comparing the sheet resistance change according to the thickness of the ruthenium thin film after atmospheric pressure O₂ plasma treatment and vacuum O2 plasma treatment.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part is said to “include” a component, this does not mean that it excludes other components, unless otherwise specifically stated, but rather that it may include other components.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

The terms used in this specification are defined as follows.

“CFx” means carbon fluorocarbon.

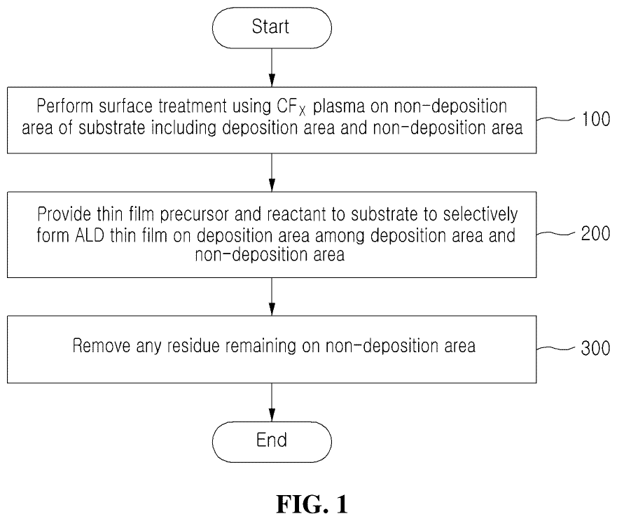

FIG. 1 is a flowchart illustrating the area selective atomic layer thin film deposition method of the disclosure.

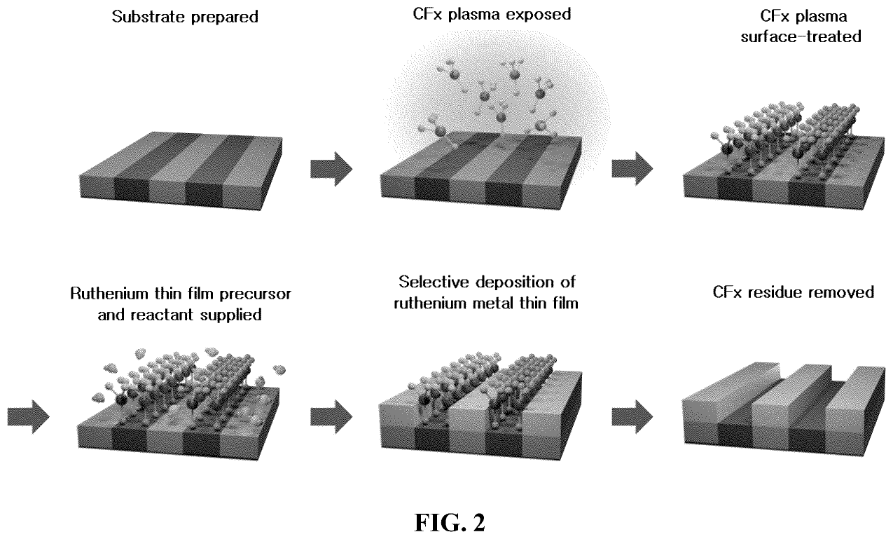

FIG. 2 is an image showing the reaction occurring on the substrate surface during the area selective atomic layer thin film deposition method of the disclosure.

Referring to FIGS. 1 and 2, an area selective atomic layer thin film deposition method according to an embodiment of the disclosure will be described.

An area selective atomic layer thin film deposition method according to an embodiment of the disclosure may include: performing surface treatment using fluorocarbon (CFx) plasma on a non-deposition area of the surface of a substrate; providing a thin film precursor and a reactant to the substrate to selectively form an atomic layer thin film on a deposition area of the substrate surface; and removing any residue remaining on the non-deposition area.

First, surface treatment using fluorocarbon (CFx) plasma is performed on the non-deposition area of the substrate surface.

Generally, substrates have high surface energy, but CFx plasma surface treatment reduces this surface energy. Once this area of reduced surface energy is created, atomic layer thin film deposition does not occur on the substrate surface.

That is, through the performing of the surface treatment, fluorocarbon functional groups may be formed on the substrate surface, and these fluorocarbon functional groups may act as inhibitors that hinder the adsorption of the thin film precursor.

The performing of the surface treatment using the CFx plasma may be performed using atmospheric pressure plasma or vacuum plasma equipment. CFx plasma may use an inert gas such as Ar, N₂, or He as the base gas.

CFx plasma may utilize an RF power of 100 W to 300 W, but this is not limited to this range.

At this time, the value of x in the CFx plasma may range from 1 to 3.9, preferably from 1 to 2.5, and most preferably, x may be 2.

Here, when x is 1, it is the same as the stoichiometric ratio of fluorographene, and when x is 2, it is the same as the stoichiometric ratio of polytetrafluoroethylene, resulting in a chemically very stable surface within this range.

Meanwhile, if the value of x in the CFx plasma is less than 1, the F vacancy concentration of the fluorocarbon material increases, inducing unstable point defects and potentially causing the adsorption of external molecules, such as metal precursors. If x exceeds 3.9, a phase transition from solid to gas may occur, preventing the plasma from functioning as an inhibitor. Therefore, it is desirable for the CFx plasma to have a value of x between 1 and 3.9, preferably between 1 and 2.5, and most preferably x is 2.

The following step involves providing a thin film precursor and reactant to the substrate to selectively form an atomic layer thin film on the deposition area of the substrate surface.

The forming of the atomic layer thin film may be performed through an atomic layer deposition process.

The forming of the atomic layer thin film may be performed at 150° C. to 450° C. Within this temperature range, the plasma-treated surface functional groups are not destroyed.

The thin film precursor may include a ruthenium, platinum, or molybdenum metal precursor. The metal thin film may be synthesized from an oxide or nitride of ruthenium, platinum, molybdenum, or ruthenium and molybdenum.

The reactant may be selected from, but is not limited to, O₂, O₃, H₂O, H₂O₂, N₂O or a metal alkoxide as an oxidizing agent.

The forming of the atomic layer thin film involves the thin film precursor being adsorbed onto the deposition area, and the thin film precursor reacting with the reactant to form a thin film. That is, through the performing of the surface treatment, fluorocarbon functional groups are formed on the substrate surface, and these fluorocarbon functional groups act as inhibitors that prevent the adsorption of the thin film precursor, transforming the surface-treated area into a non-deposition area.

After the precursor is injected, a purge process leaves only the chemically adsorbed precursor, while the physically adsorbed precursor is discharged through the pumping line. At this time, the non-deposition area is free of chemically and physically adsorbed precursors.

Subsequently, during the oxidizer injection process, the precursor adsorbed in the deposition area reacts with the oxidizer, forming a metal or metal oxide thin film.

The next step is to remove any remaining residue on the non-deposition area.

This residue removal step may be performed using vacuum or atmospheric pressure O₂ plasma or ozone.

In the disclosure, examples were conducted using the same process sequence as in FIG. 1, using 2 sccm of C₄F₈ as a fluorocarbon plasma and 5 LPM of He as a base gas. Ruthenium was used as the metal.

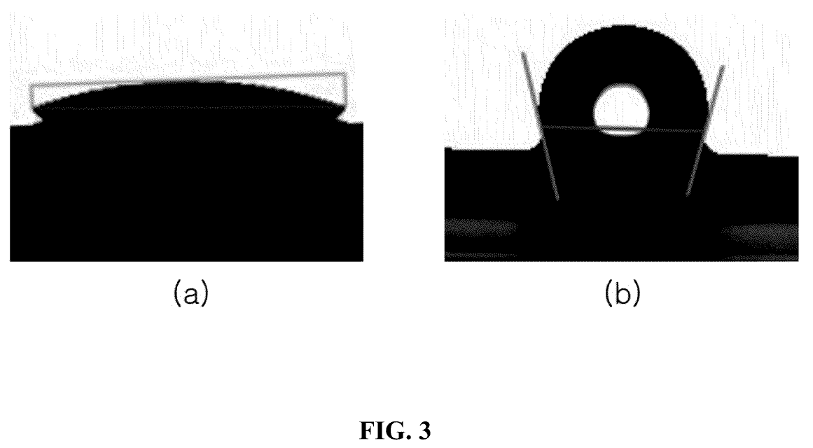

FIG. 3 shows contact angle images (a) before and (b) after CFx plasma surface treatment.

Referring to FIG. 3, it is possible to confirm that after CFx plasma surface treatment, the surface becomes hydrophobic, and even if a precursor is supplied thereafter, the precursor is not adsorbed on the surface.

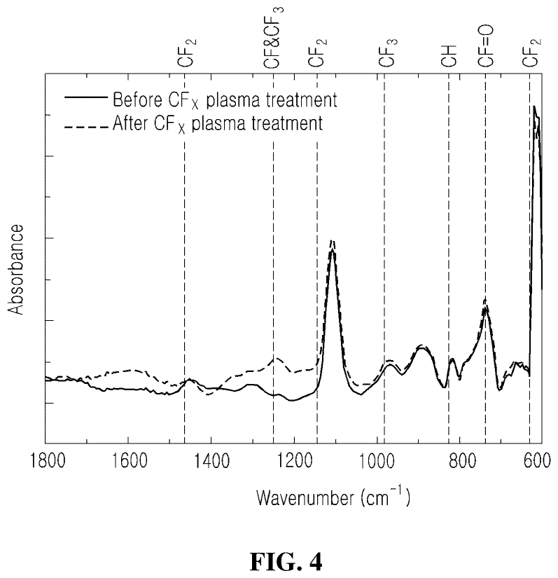

FIG. 4 is an FT-IR graph before and after CFx plasma surface treatment.

Referring to FIG. 4, it is possible to confirm that CFx functional groups are formed on the surface after CFx plasma surface treatment, and that these functional groups act as inhibitors that prevent the adsorption of precursors during the subsequent selective deposition of a thin film.

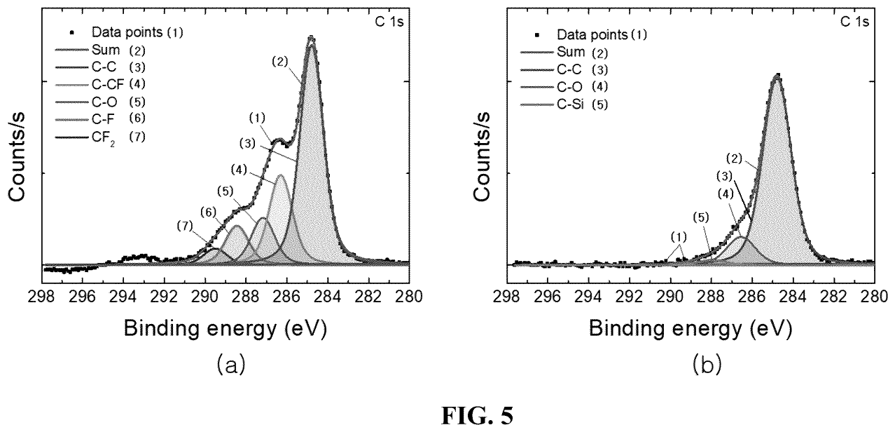

FIG. 5 shows XPS data (a) after CFx plasma surface treatment and (b) after CFx residue removal using atmospheric pressure O₂ plasma.

Referring to FIG. 5, it is possible to confirm that the CFx residue is removed through atmospheric pressure O₂ plasma, and thus no data appears in (b).

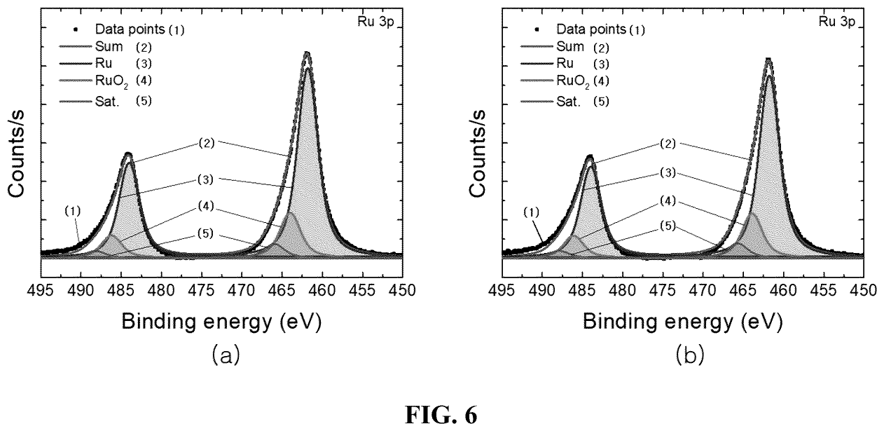

FIG. 6 shows XPS data of a ruthenium thin film (a) before and (b) after atmospheric pressure O₂ plasma treatment.

Referring to FIG. 6, atmospheric pressure O₂ plasma utilizes its weak oxidizing power, which does not significantly alter the thin film surface structure, and this allows it to selectively remove CFx residues in the non-deposition area, while maintaining the physical properties of the ruthenium thin film in the deposition area. After selective deposition of a ruthenium thin film, atmospheric pressure O₂ plasma is confirmed to be suitable for removing CFx residues in the non-deposition area.

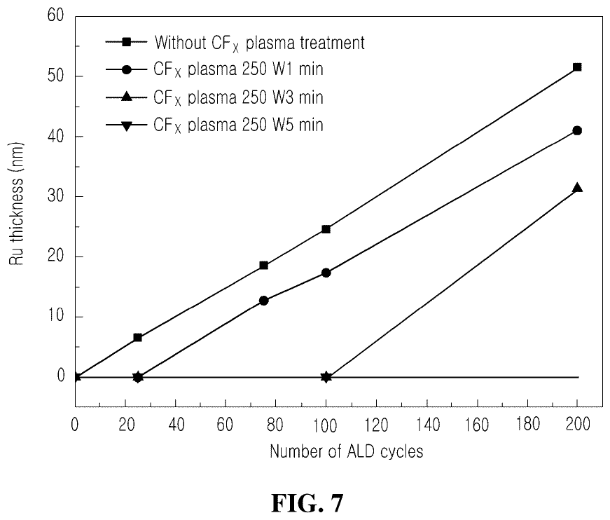

FIG. 7 shows the results of selective deposition of a ruthenium metal thin film using the area selective atomic layer thin film deposition method of the disclosure. The thickness was measured using ellipsometric analysis.

Referring to FIG. 7, CFx plasma surface treatment may increase the ruthenium thin film growth delay time. That is, selective deposition can be achieved by selecting appropriate CFx plasma surface treatment conditions. The surface-treated area gradually degrades due to the oxidizing agent (ozone or oxygen) used during atomic layer deposition, reducing its inhibitory performance; however, durability can be controlled by adjusting the surface treatment time and power. Theoretically, infinite selectivity can be achieved, and in examples, selectivity up to 50 nm ruthenium thin films can be observed.

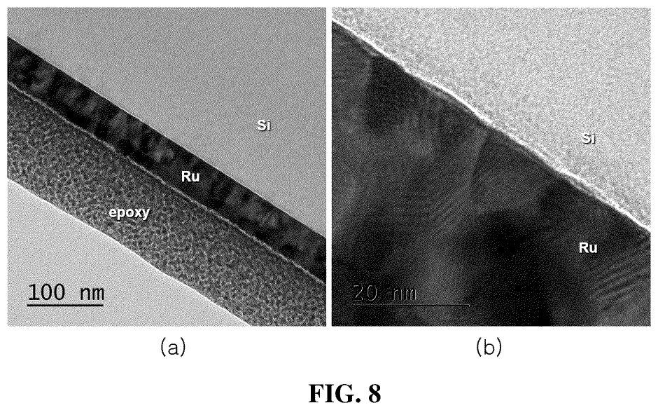

FIG. 8 shows (a) the interface between a ruthenium thin film deposited without CFx plasma treatment and the substrate, and (b) a magnified image of the interface. (FIG. 7—without CFx plasma treatment, 100 cycles of Ruthenium ALD)

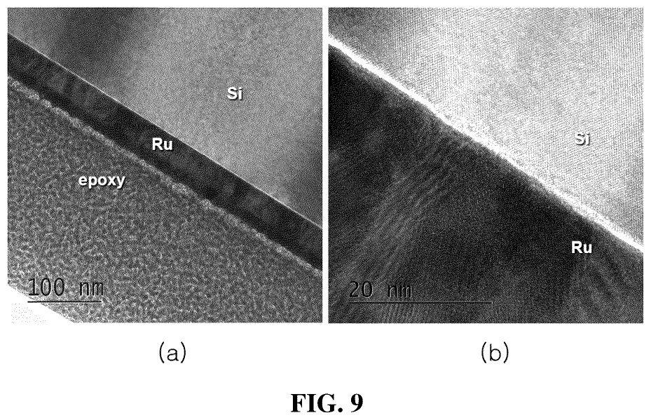

FIG. 9 shows (a) the interface of a substrate treated with CFx plasma at 250 W for 1 minute to form an inhibitor, followed by Ruthenium ALD to exceed the selectivity, and (b) a magnified image of the substrate. (FIG. 7—CFx plasma at 250 W, 3 minutes, 200 cycles of Ruthenium ALD)

Referring to FIGS. 8 and 9, it is possible to confirm that ruthenium grows without residue at the interface even on the CFx-treated substrate. This demonstrates that the thickness of atomic layer deposition in specific areas can be controlled by controlling the CFx surface treatment time.

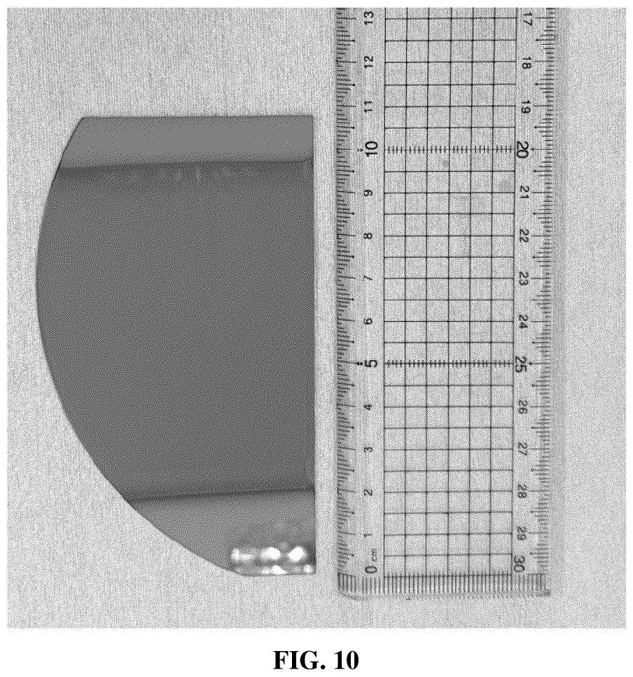

FIG. 10 shows images of wafer-scale surface treatment using controlled plasma head movement.

Referring to FIG. 10, it is possible to confirm that wafer-scale surface treatment is possible by controlling the degree of movement of the plasma head.

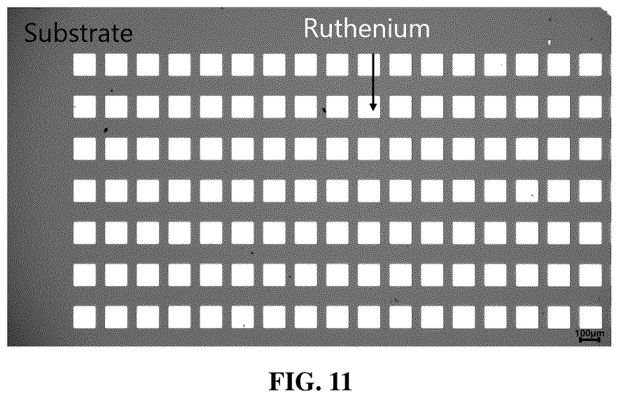

FIG. 11 shows images comparing ruthenium deposition on untreated and treated areas with CFx plasma.

Referring to FIG. 11, it is possible to confirm that the substrate remains intact in the areas inhibited by CFx, while ruthenium is deposited only in the uninhibited areas.

Referring to FIG. 11, it is possible to confirm that the substrate remains intact in the areas inhibited by CFx, while ruthenium is deposited only in the uninhibited areas.

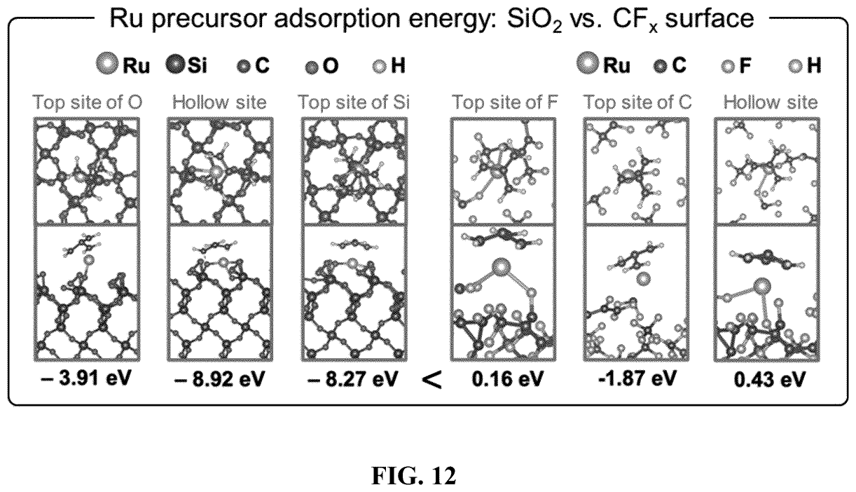

FIG. 12 shows the results of an Adsorption Energy Density Functional Theory (DFT) calculation of the ruthenium precursor to explain the inhibition principle of the CFx plasma surface treatment used in the disclosure.

Referring to FIG. 12, the ruthenium precursor is adsorbed on the growth area, the SiO₂ surface, by stably bonding with oxygen (O) or silicon (Si) atoms; however, in the non-deposition area, which is surface-treated with CFx functional groups, the precursor adsorption is energetically very unstable.

This inhibition can be attributed to the energetic disadvantage of Ru precursor adsorption on the CFx surface compared to the SiO₂ surface.

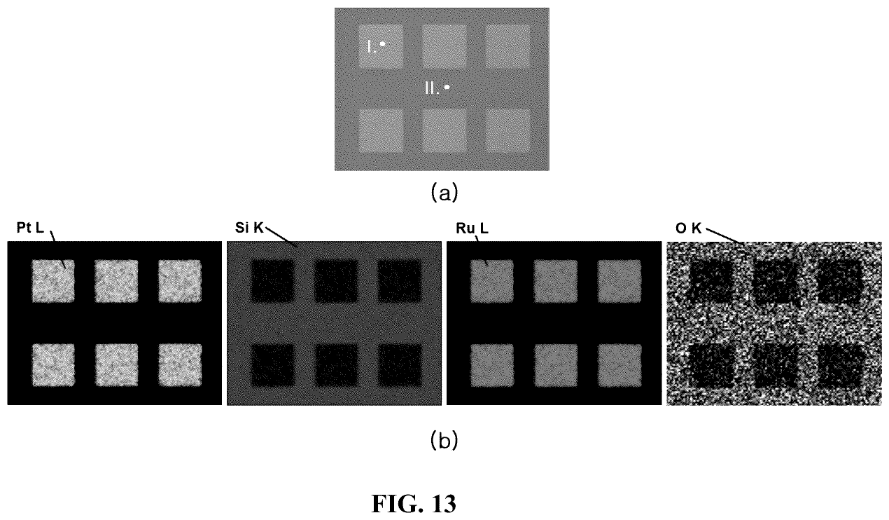

FIG. 13 shows (a) a scanning electron microscope (SEM) image and (b) an energy dispersive spectroscopy (EDS) analysis result to confirm the selectivity of a selective atomic layer deposition process for a ruthenium thin film on a SiO₂ substrate patterned with a Pt thin film according to the method of the disclosure. Since CFx has a weak bond with metals such as Pt, it may be selectively formed only on dielectric substrates.

FIG. 13(a) visually confirms the formation of a clear pattern, with a thin film deposited in a specific area (I) and not deposited in another area (II).

FIG. 13(b) shows a line scan analysis along the red line in the image and the results of component analysis at a specific point (Point). In the line scan results, Pt (substrate) and Ru (deposition material) signals were clearly observed in the deposition area (I), but in the non-deposition area (II), these signals were absent, and only Si and O signals were detected.

Furthermore, the quantitative analysis of the components at each point is shown as in Tables 1 and 2.

TABLE 1

| Element | Atomic % |
|---|---|
| O K | 5.05 |
| Si K | 72.21 |
| Ru L | 2.46 |
| Pt M | 20.28 |
| Totals | 100 |

TABLE 2

| Element | Atomic % |
|---|---|
| O K | 19.94 |
| Si K | 80.06 |
| Ru L | 0.0 |
| Pt M | 0.0 |
| Totals | 100 |

Looking at Tables 1 and 2 above, it is possible to confirm that approximately 2.46% ruthenium (Ru) is present in the deposition area (I), but no ruthenium is detected in the non-deposition area (II).

This quantitatively confirms that the area selective deposition according to the disclosure was performed perfectly with very high selectivity.

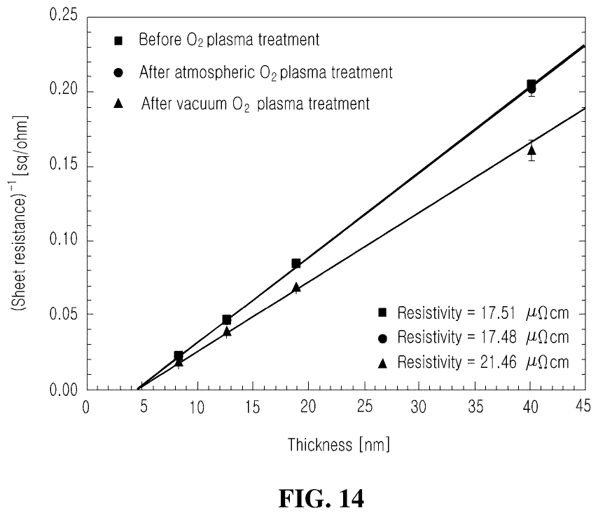

FIG. 14 shows the results of a quantitative evaluation of the effect of the atmospheric pressure O₂ plasma process on the electrical characteristics of a ruthenium thin film.

FIG. 14 shows a graph comparing the sheet resistance values calculated from measurements taken before O₂ plasma treatment, after atmospheric pressure O₂ plasma treatment, and after vacuum O₂ plasma treatment as a control group, wherein the resistance of the ruthenium thin film before O₂ plasma treatment was 17.51 μΩcm, while the resistance after atmospheric pressure O₂ plasma treatment was 17.48 μΩcm, showing virtually no change.

On the other hand, when treated with vacuum O₂ plasma, the resistance increased significantly to 21.46 μΩcm, which may indicate a deterioration in electrical properties due to oxidation of the thin film.

The experimental results described above reaffirm that the inhibitor can be completely removed after selective deposition, and that no ruthenium (Ru) degradation occurs during this removal process.

In conclusion, unlike prior technologies, the disclosure utilizes atmospheric plasma, eliminating the need for separate vacuum environment creation and joint sealing processes, and this simplifies the process and reduces processing time; furthermore, by appropriately adjusting atmospheric plasma power and treatment time, the inhibitor duration and, consequently, the deposition selectivity can be controlled, facilitating application to complex structures.

Above all, the disclosure can be utilized for the selective deposition of a variety of materials, regardless of precursor type.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. An area selective atomic layer thin film deposition method, comprising:
performing surface treatment using fluorocarbon (CFx) plasma on a non-deposition area of a surface of a substrate;
providing a thin film precursor and a reactant to the substrate to selectively form an atomic layer thin film on a deposition area of the surface of the substrate; and
removing any residue remaining on the non-deposition area.

2. The area selective atomic layer thin film deposition method of claim 1, wherein through the performing the surface treatment, a fluorocarbon functional group is formed on the surface of the substrate, and the fluorocarbon functional group acts as an inhibitor that prevents an adsorption of the thin film precursor.

3. The area selective atomic layer thin film deposition method of claim 1, wherein a value of x of the fluorocarbon (CFx) is in a range of 1 to 3.9.

4. The area selective atomic layer thin film deposition method of claim 1, wherein the performing the surface treatment using the fluorocarbon plasma is performed using atmospheric pressure plasma or vacuum plasma equipment.

5. The area selective atomic layer thin film deposition method of claim 1, wherein the forming the atomic layer thin film is performed through an atomic layer deposition process.

6. The area selective atomic layer thin film deposition method of claim 1, wherein the forming the atomic layer thin film is performed at a temperature range of 150° C. to 450° C.

7. The area selective atomic layer thin film deposition method of claim 1, wherein the thin film precursor comprises at least one of a ruthenium, platinum or molybdenum metal precursor.

8. The area selective atomic layer thin film deposition method of claim 1, wherein the reactant is selected from O₂, O₃, H₂O, H₂O₂, N₂O or metal alkoxide as an oxidizing agent.

9. The area selective atomic layer thin film deposition method of claim 1, wherein in the forming the atomic layer thin film, the thin film precursor is adsorbed to the deposition area, and the thin film precursor and the reactant react to form a thin film.

10. The area selective atomic layer thin film deposition method of claim 1, wherein the thin film precursor is not chemically adsorbed on the non-deposition area of the substrate.

11. The area selective atomic layer thin film deposition method of claim 1, wherein the removing of the residue is performed through a process selected from a group consisting of vacuum O₂ plasma, atmospheric pressure O₂ plasma, vacuum ozone, and atmospheric pressure ozone.
